(19) United States
(12) Patent Application Publication
(10) Pub. No.: US 2012/0194491 A1
(43) Pub. Date: Aug. 2, 2012

(54) DISPLAY DEVICE

(75) Inventor: Kentaroh Ryuh, Osaka (JP)

(73) Assignee: SHARP KABUSHIKI KAISHA, Osaka (JP)

(21) Appl. No.: 13/501,149

(22) PCT Filed: Sep. 6, 2010
(86) PCT No.: PCT/JP2010/065204

§ 371 Date: Apr. 10, 2012

(30) Foreign Application Priority Data
Oct. 14, 2009 (JP) 2009-237461
Apr. 14, 2010 (JP) 2010-093173

(51) Int. Cl. H05K 5/04; G09G 5/00; G02F 1/1333

(52) U.S. Cl. 345/206; 361/752; 349/58

(57) ABSTRACT

The present invention is aimed to provide a display device that has improved reliability of an electrical connection between a case and a conductive pattern for the ground potential on a control substrate. The display device of the present invention includes a liquid crystal panel 11, an underside cabinet Cb that supports the liquid crystal panel 11 and that has electrical conductive properties, and a control substrate 40 that performs display-related control of the liquid crystal panel 11. A conductive pattern 41 to be applied with a ground potential is formed on the control substrate 40, a solder 42 that electrically connects the conductive pattern 41 to the underside cabinet Cb is formed on the conductive pattern 41, and the solder 42 has an endless annular shape in plan view.

### TECHNICAL FIELD

The present invention relates to a display device.

### BACKGROUND ART

In electronic equipment formed by housing in a case a circuit board having electronic circuits formed thereon, there has been a demand for reducing the effect of noise. For example, in liquid crystal display devices with an on-board car navigation system or the like, noise from the outside has an adverse effect on a control substrate for controlling the liquid crystal panel, for instance, so there is a possibility of occurrence of phenomenon that a display image is not displayed normally. As a countermeasure against the aforementioned noise, there is a device having a configuration in which a case and a conductive pattern that is formed on a control substrate and that serves as a ground potential (ground pattern) are electrically connected (Patent Document 1 mentioned below). In the device having the configuration of Patent Document 1, a spring having electrical conductive properties is interposed between the conductive pattern and the case. The operational reliability of the control substrate is improved by electrically connecting the conductive pattern and the case via this spring.

### RELATED ART DOCUMENTS

### Patent Documents

Patent Document 1: Japanese Patent Application Laid-Open Publication No. 2003-315888

### Problems to be Solved by the Invention

In the device described in the aforementioned Patent Document 1, a dedicated separate member (spring) is required to connect the conductive pattern and the case, so the parts cost is increased. Therefore, as an alternative connection scheme to suppress the cost to some extent, it would also be possible to perform the electrical connection between the conductive pattern and the case via a solder, but in this case, it becomes important to form the solder such that the height thereof is uniform over the entire surface (contact surface with the case). If the height of the solder is not uniform, the solder and the case contact only partially, so the contact surface area between the two becomes small; as a result, there is a concern that the electrical connection between the conductive pattern and the case may not be established reliably.

### SUMMARY OF THE INVENTION

The present invention was perfected based on the aforementioned circumstances, and an object thereof is to provide a display device in which the reliability of an electrical connection between a case and a conductive pattern serving as a ground potential is improved.

### Means for Solving the Problems

In order to solve the aforementioned problems, the display device of the present invention is a display device which includes a display panel, a case that supports the display panel, the case being electrically conductive, a control substrate that performs display-related control, a conductive pattern to be applied with a ground potential, formed on the control substrate, and a solder that electrically connects the conductive pattern to the case, the solder being formed on this conductive pattern, wherein the solder has an endless annular shape in plan view.

In general, a solder in a molten state is such that the central portion bulges due to surface tension, while the end portion becomes lower than the central portion. Therefore, in cases where the case and the conductive pattern are connected via a solder, the end portion of the solder becomes a site that is harder to make contact with the case than the central portion thereof. If the contact with the case were to be made solely by the central portion of the solder, the contact surface area between the solder and the case would become small, and lowering reliability of electrical connection would become a concern. In light of this, the solder is formed in an endless annular shape in the present invention. With an endless annular shape, there is no end portion in the circumferential direction of the solder, so the height from the control substrate easily becomes uniform. Consequently, the solder can be caused to contact the case reliably over the entire circumference thereof, so it is possible to improve the reliability of an electrical connection between the conductive pattern and the case. As a result, the ground potential of the control substrate can be made more stable, so the control substrate becomes less susceptible to the effect of noise, thus improving the operational reliability of the control substrate. Note that, the phrase the case “supports the display panel” referred to here means that the case is involved in the attachment of the display panel in some form, and it is sufficient if the display panel is supported either directly or indirectly by the case. For instance, this includes a case that indirectly houses the display panel within its own space or the like as well as a case that directly supports the display panel.

In the aforementioned configuration, a display control substrate that performs display control of the display panel is an example of the control substrate. If such a configuration is adopted, the display control of the display panel can be performed in a more stable manner.

Furthermore, a light source that supplies light to the display panel can be provided, and a light-source control substrate that performs driving control of the light source can be an example of the control substrate. If such a configuration is adopted, the drive control of the light source can be performed in a more stable manner.

Moreover, a bent part can be formed by stamping and bending a portion of the case toward the control substrate, and the solder can be electrically connected to the bent part. If a configuration is adopted in which the control substrate and the case are thus electrically connected via the bent part which is a portion of the case, there no longer is the need for a separate member (e.g., on-board contact) for electrically connecting the control substrate and the case.

In addition, the control substrate can be disposed so as to face a bottom wall of the case, and the bent part can be a portion of the bottom wall. If a portion of the bottom wall that faces the control substrate is formed as the bent part, the amount of bending of the bottom wall that is required in the formation of the bent part is relatively small, so the formation of the bent part becomes easy.

Furthermore, the bent part can have an inclined part that is inclined toward the control substrate and a tip part that extends from a tip of the inclined part along a planar surface of the control substrate, the tip part being in contact with the solder. If a configuration is adopted in which the tip part that extends along the plate surface of the control substrate is caused to contact the solder, the inclination of the tip part toward the solder can be suppressed, so the soldering of the case and the control substrate can be performed more reliably.

Moreover, the conductive pattern can be formed on a surface of the control substrate facing the case. If a configuration is adopted in which the conductive pattern and the case face each other, soldering of the two (connection via the solder) can be performed easily.

In addition, the case can be an external box defining external appearance of the display device. If the case is such an external box, the size of the case (that is, the size of the conductor) can be set large, so the ground potential of the control substrate can be made more stable.

Furthermore, a liquid crystal panel using liquid crystal can be an example of the display panel. Such a display device can be suited as a liquid crystal display device to various applications, for example, besides display devices for a car navigation system, desktop screens for televisions or personal computers, and the like.

### Effects of the Invention

With the present invention, it is possible to provide a display device in which the reliability of an electrical connection between a case and a conductive pattern that serves as the ground potential in a control substrate is improved.

### BRIEF DESCRIPTION OF THE DRAWINGS

FIG. 1 is a sectional view showing the configuration of a cross section along the direction of the long side of the liquid crystal display device according to Embodiment 1 of the present invention.

FIG. 2 is an exploded perspective view showing a schematic configuration of the liquid crystal display device.

FIG. 3 is a sectional view showing the configuration of a cross section along the direction of the short side of the liquid crystal display device.

FIG. 4 is an enlarged sectional view along the direction of the long side showing the connecting structure between a control substrate and an underside cabinet.

FIG. 5 is an enlarged sectional view along the direction of the short side showing the connecting structure between the control substrate and the underside cabinet.

FIG. 6 is a plan view showing a solder formed on a conductive pattern.

FIG. 7 is a sectional view showing the solder formed on the conductive pattern.

FIG. 8 is a plan view showing a comparative example.

FIG. 9 is an enlarged sectional view along the direction of the long side showing the comparative example.

FIG. 10 is an enlarged sectional view along the direction of the short side showing the comparative example.

FIG. 11 is an enlarged sectional view showing the configuration of a cross section along the direction of the long side of the liquid crystal display device according to Embodiment 2.

FIG. 12 is a sectional view showing the configuration of a cross section along the direction of the long side of the liquid crystal display device according to Embodiment 3.

FIG. 13 is a perspective view showing a solder according to Embodiment 4.

### DETAILED DESCRIPTION OF EMBODIMENTS

### Embodiment 1

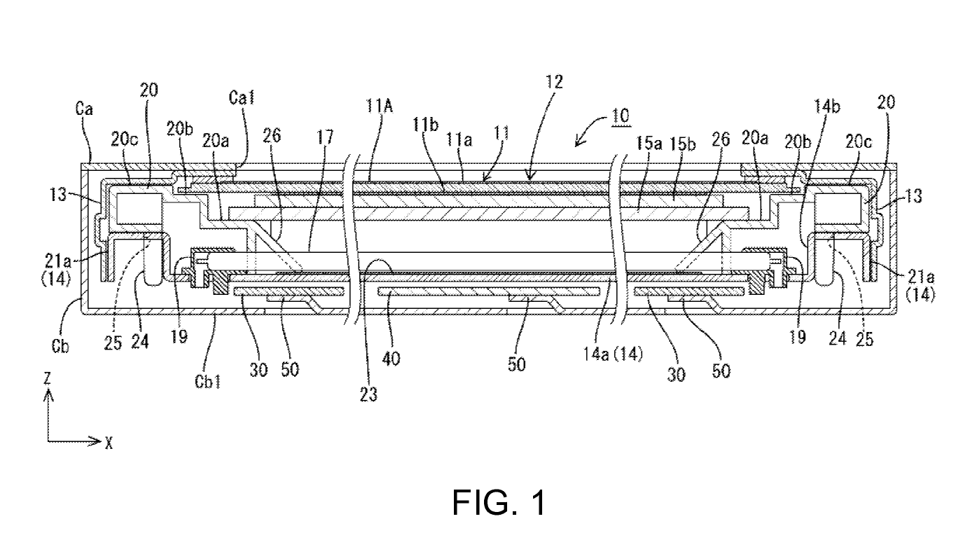

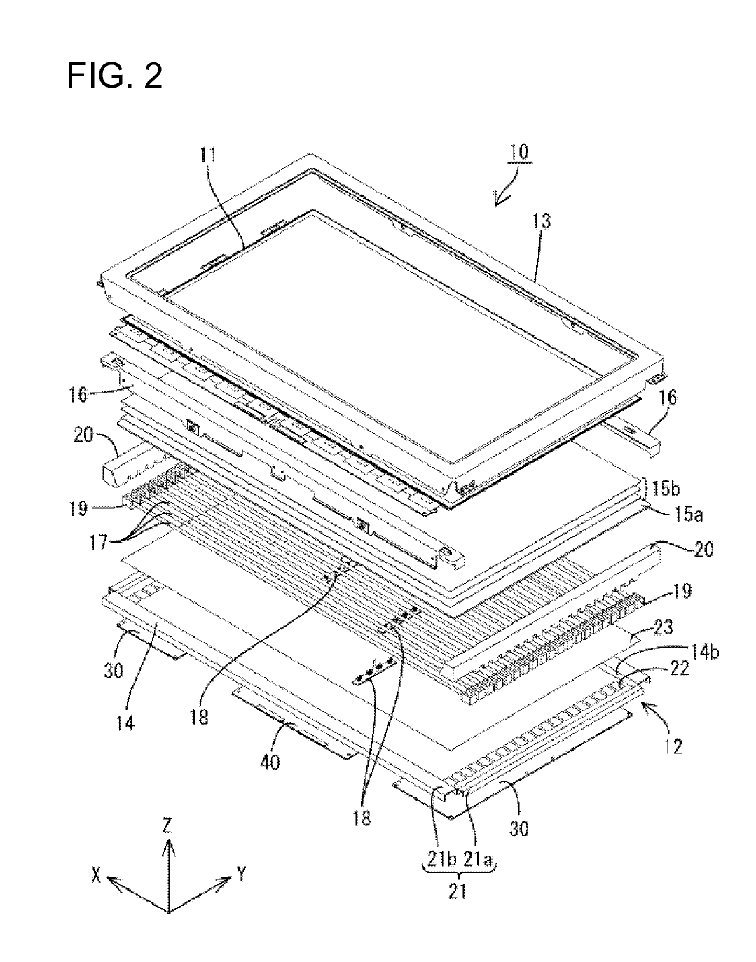

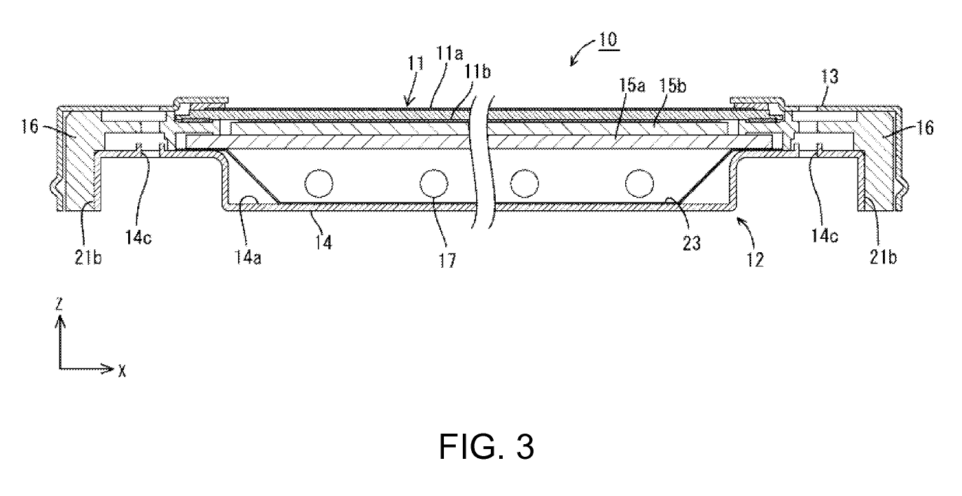

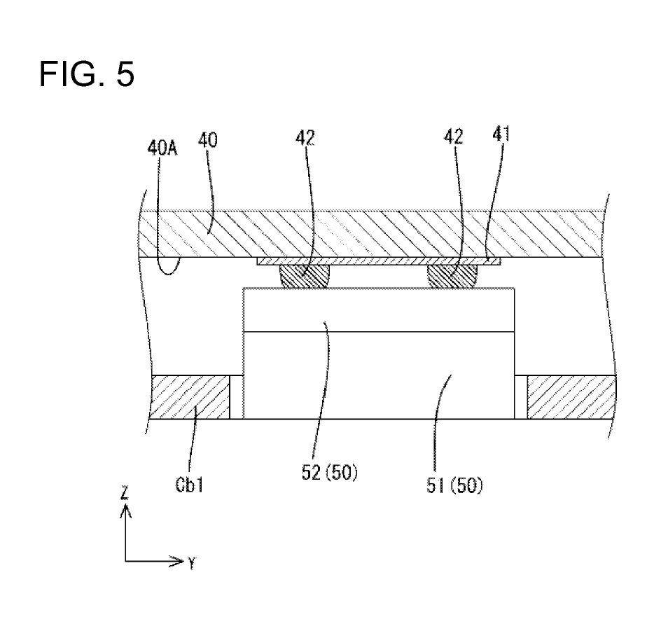

The configuration of the liquid crystal display device 10 according to Embodiment 1 of the present invention will be described using FIGS. 1 to 10. The liquid crystal display device 10 of the present embodiment is used for a car navigation device, television receiver, or the like, for example. FIG. 1 is a sectional view showing the configuration of a cross section along the direction of the long side of the liquid crystal display device 10, FIG. 2 is an exploded perspective view showing a schematic configuration of the liquid crystal display device 10, and FIG. 3 is a sectional view showing the configuration of a cross section along the direction of the short side of the liquid crystal display device. Note that the direction of the long side of the liquid crystal display device 10 (and a chassis 14) is taken as the X-axis direction, the direction of the short side is taken as the Y-axis direction, and the up-down direction in FIG. 1 is taken as the Z-axis direction (front-back direction).

As shown in FIGS. 1 and 2, the liquid crystal display device 10 (display device) according to the present embodiment has a horizontally elongated square shape (rectangular shape) as a whole and is installed in a state in which the direction of the short side is caused to coincide with the vertical direction, for instance. The liquid crystal display device 10 includes a liquid crystal panel 11 (display panel) and a backlight device 12 (illumination device) as the external light source and is designed such that these are integrally held by a frame-form bezel 13 or the like. Furthermore, the liquid crystal display device 10 includes a front-side cabinet Ca and an underside cabinet Cb which constitute an external box that defines the external appearance of the liquid crystal display device 10.

Both the front-side and underside cabinets Ca and Cb (case) are used to house both the liquid crystal panel 11 and the backlight device 12 in a sandwiching manner, and are made of metal having electrical conductive properties, for example. The underside cabinet Cb disposed on the back side (lower side in FIG. 1) has a substantially box shape that is open on the front side (upper side in FIG. 1) and supports the backlight device 12 while housing this backlight device in the interior thereof. The front-side cabinet Ca disposed on the front side (upper side in FIG. 1) has the shape of a frame in which an open part Cal is formed, and is attached to the underside cabinet Cb so as to cover the opening thereof from the front side. Moreover, the display surface 11A of the liquid crystal panel 11 is exposed from the opening part Cal. Note that the cabinets Ca and Cb are omitted from the illustration in FIG. 3.

Next, the liquid crystal panel 11 and the backlight device 12 that make up the liquid crystal display device 10 will be described. The liquid crystal panel 11 has a configuration in which a pair of glass substrates are bonded together with a prescribed gap therebetween, and a liquid crystal is sealed in between the two glass substrates. One of the glass substrates is provided with switching elements (e.g., TFTs) connected to source wiring lines and gate wiring lines that are orthogonal to each other, pixel electrodes connected to these switching elements, an alignment film, and the like, while the other glass substrate is provided with a color filter in which respective colored parts such as red (R), green (G), and blue (B) are disposed in a specified arrangement, an opposite electrode, an alignment film, and the like. Note that polarizing plates 11a and 11b are disposed on the outside of the two glass substrates.

As shown in FIGS. 1 and 2, the backlight device 12 includes a chassis 14 having a substantially box shape that is open on the front side, a diffusion plate 15a attached so as to cover the opening part 14b of the chassis 14, a plurality of optical sheets 15b disposed between the diffusion plate 15a and the liquid crystal panel 11, and frames 16 that are disposed along the long sides of the chassis 14 and that hold the long-side edge portions of the diffusion plate 15a by sandwiching it with the chassis 14 (see FIG. 3).

As shown in FIG. 2, the chassis 14 includes on the inside thereof cold cathode tubes 17 (light source) that supply light to the liquid crystal panel 11, lamp clips 18 for attaching the cold cathode tubes 17 to the chassis 14, relay connectors 19 that perform the relay of electrical connection at the respective end portions of the cold cathode tubes 17, and holders 20 that respectively cover, in a collective manner, sets of the relay connectors 19 and the end portions of a set of the cold cathode tubes 17. Note that in this backlight device 12, the side of the diffusion plate 15a as opposed to the cold cathode tubes 17 constitutes the light emission side (front side).

The chassis 14 is made of aluminum, for example, and has electrical conductive properties. The chassis 14 is made by sheet-metal working into a shallow substantially box shape which is composed of a rectangular bottom plate 14a and bent-back outer edge portions 21 (bent-back outer edge portions 21a in the direction of the short side and bent-back outer edge portions 21b in the direction of the long side) that rise from the respective sides of the bottom plate 14a and are bent back to be substantially in a U shape. Note that in the present embodiment, the chassis 14 is made of aluminum, intending to reduce the weight thereof, but in cases where a higher bending strength is required, for instance, the chassis may also be made of metal such as an iron-based material. As shown in FIG. 2, a plurality of attachment holes 22 for attaching the relay connectors 19 are provided in the bottom plate 14a of the chassis 14 at both end portions in the direction of the long side thereof. In addition, as shown in FIG. 3, fastening holes 14c are provided in the upper surfaces of the bent-back outer edge portions 21b of the chassis 14, thereby making it possible to untie the bezel 13, frames 16, chassis 14, and the like by means of screws or the like, for example.

A reflective sheet 23 is provided on the side of the front surface (on the side facing the cold cathode tubes 17) of the bottom plate 14a of the chassis 14. The reflective sheet 23 is made of a synthetic resin, with the surface thereof having a white color superior in terms of light reflectivity, and is laid along the inner surface of the bottom plate 14a of the chassis 14 so as to cover substantially the entire surface thereof. This reflective sheet 23 makes it possible to reflect light emitted from the cold cathode tubes 17 toward the diffusion plate 15a.

Furthermore, the diffusion plate 15a and the optical sheets 15b are provided on the side of the opening part 14b of the chassis 14. The diffusion plate 15a is formed by dispersing and mixing light-scattering particles into a plate-form member made of synthetic resin, and has the function of diffusing linear light emitted from the cold cathode tubes 17 constituting tube-form light source. The short-side edge portions of the diffusion plate 15a are carried on first surfaces 20a of the holders 20 (described later) and are therefore not subjected to any binding force in the up-down direction. Meanwhile, the long-side edge portions of the diffusion plate 15a are fixed by being respectively sandwiched between the chassis 14 (reflective sheet 23) and the frames 16 (see FIG. 3).

The optical sheets 15b disposed on the diffusion plate 15a are lamination of a diffusion sheet, a lens sheet, and a reflective polarizing plate in that order from the side of the diffusion plate 15a and have the function of converting the light that has emitted from the cold cathode tubes 17 and passed through the diffusion plate 15a into planar light. The liquid crystal panel 11 is installed on the side of the upper surface of these optical sheets 15b, and these optical sheets 15b are sandwiched between the diffusion plate 15a and the liquid crystal panel 11. Note that the configuration of the optical sheets 15b is not limited to the aforementioned configuration, and the number of laminations of the diffusion sheet, lens sheet, reflective polarizing plate, and the like, the order of lamination, and the like can be modified as appropriate.

Each of the cold cathode tubes 17 has a long and narrow tube shape, and a plurality of these cold cathode tubes 17 are housed inside the chassis 14 in a state in which the direction of the length thereof (axial direction) is caused to coincide with the long-side direction of the chassis 14. The respective cold cathode tubes 17 are disposed in positions directly below the liquid crystal panel 11 in a state of being lined up parallel to each other. That is, the backlight device 12 in the present embodiment is a so-called direct-type backlight device. The cold cathode tubes 17 are, as a result of being held by the lamp clips 18 (see FIG. 2), placed in a state in which a slight gap is provided between these cold cathode tubes 17 and the bottom plate 14a (reflective sheet 23) of the chassis 14 (see FIG. 1). The respective end portions of the cold cathode tubes 17 are fitted into the relay connectors 19, and the holders 20 are attached so as to cover these relay connectors 19.

The holders 20 covering the end portions of the cold cathode tubes 17 are made of synthetic resin having a white color and have a slender and substantially box shape that extends along the short-side direction of the chassis 14 as shown in FIG. 2. As shown in FIG. 1, these holders 20 have stair-like surfaces that can carry the diffusion plate 15a and the liquid crystal panel 11 at different levels on the side of the front surfaces thereof, and are disposed in a state of being partially superimposed above the bent-back outer edge portions 21a in the short-side direction of the chassis 14, thus forming the side walls of this backlight device 12 together with the bent-back outer edge portions 21a. Insertion pins 24 protrude from the surface of each holder 20 that faces the corresponding bent-back outer edge portion 21a of the chassis 14, and these holders 20 are attached to the chassis 14 as a result of these insertion pins 24 being inserted into insertion holes 25 formed in the upper surfaces of the bent-back outer edge portions 21a of the chassis 14.

The stair-like surfaces of the holders 20 are composed of three surfaces parallel to the bottom plate 14a of the chassis 14, and the short-side edge portions of the diffusion plate 15a are carried on the first surfaces 20a positioned at the lowest. Moreover, inclined covers 26 that are inclined toward the bottom plate 14a of the chassis 14 extend from the first surfaces 20a. The short-side edge portions of the liquid crystal panel 11 are carried on second surfaces 20b of the stair-like surfaces of the holders 20. Third surfaces 20c positioned at the highest of the stair-like surfaces of the holders 20 are respectively disposed in positions that are superimposed above the bent-back outer edge portions 21a of the chassis 14 and contact the bezel 13.

As described above, the backlight device 12 (chassis 14) is housed by being sandwiched between both the front and back cabinets Ca and Cb, and the bezel 13 is attached to the front-side cabinet Ca, for example (see FIG. 1). Then, as described above, the bezel 13 is attached to the chassis 14, and the holders 20 are attached to the chassis 14. Then, the liquid crystal panel 11 is supported on the chassis 14 via the holders 20. Specifically, a configuration is adopted in which the liquid crystal panel 11 is supported (indirectly) by the front-side cabinet Ca, and hence the underside cabinet Cb, that make up a case. Note that, “the underside cabinet Cb supports the liquid crystal panel 11” referred to here means that the underside cabinet Cb is involved in the attachment of the liquid crystal panel 11, and it would be sufficient if the display panel is supported either directly or indirectly by the underside cabinet Cb. For instance, the liquid crystal panel 11 may also be attached directly to the underside cabinet Ca.

Next, the configuration of the backlight device 12 on the back surface side (the surface of the chassis 14 on the side opposite from the side on which the cold cathode tubes 17 are disposed) will be described in detail using FIGS. 1 and 4 to 7. Two types of control substrate (inverter substrates 30 and a control substrate 40) that perform display-related control of the liquid crystal panel 11 are attached to the back surface of the chassis 14 (the surface of the bottom plate 14a on the side opposite from the side oriented toward the cold cathode tubes 17). The inverter substrates 30 (light-source control substrates) supply power to the cold cathode tubes 17 and control the driving of the cold cathode tubes 17, being provided in a pair at either end portion of the chassis 14 in the long-side direction (left and right in FIG. 1).

The control substrate 40 (display control substrate) controls the display of the liquid crystal panel 11 and is disposed between the pair of inverter substrates 30 in the long-side direction of the chassis 14. The control substrate 40 includes, for instance, a gate driver that controls the potential of each gate wiring line in the liquid crystal panel 11, a source driver that converts an image data signal to voltage and applies it to each pixel electrode, a synchronous circuit that synchronizes the gate driver and the source driver, an image data output circuit that outputs image data signals to the source driver, and the like. Note that the control substrate 40 may also be configured from circuits other than the ones described above, and any types of circuit can be applied as long as these are circuits that control the display on the liquid crystal panel 11.

As shown in FIG. 1, the two inverter substrates 30 and the control substrate 40 are disposed so as to face the bottom plate Cb1 of the underside cabinet Cb (bottom wall of the case). In other words, the plate surfaces of the two inverter substrates 30 and control substrate 40 are disposed along the direction of plane of the bottom plate Cb1. Bent parts 50 are respectively formed in the bottom plate Cb1 in locations corresponding to the two inverter substrates 30 and the control substrate 40 by stamping portions of the bottom plate Cb1 and bending these portions toward the front (direction toward the inverter substrates 30 and control substrate 40). The individual bent parts 50 are formed so as to respectively contact the back surfaces (the surfaces facing the bottom plate Cb1) of the inverter substrates 30 and control substrate 40. The individual bent parts 50 have the function of electrically connecting the respective control substrates that these bent parts make contact therewith the underside cabinet Cb.

Next, the connecting structure that electrically connects the control substrate 40 and the corresponding bent part 50 will be described. Note that the structure connecting the control substrate 40 and the bent part 50 and the structure connecting the inverter substrates 30 and the bent parts 50 are the same structure (connecting structure via a solder 42, which will be described later). Therefore, only the structure connecting the control substrate 40 and the corresponding bent part 50 will be described here, and the description of the structure connecting the inverter substrates 30 and the corresponding bent parts 50 will be omitted.

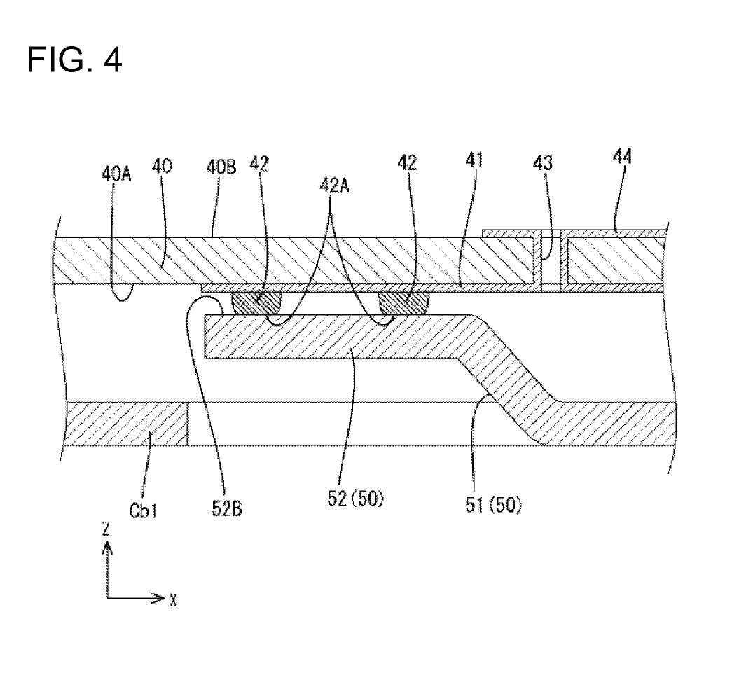

As shown in FIG. 4, the bent part 50 is configured of an inclined part 51 that is inclined toward the control substrate 40 and a tip part 52 that extends from the tip of the inclined part 51 along the plate surface of the control substrate 40. The inclined part 51 extends from the bottom plate Cb1 so as to be inclined toward the control substrate 40. The tip part 52 has the shape of a flat plate in plan view, and the size in the direction of plane thereof is set at a size that covers solder 42 (described later). In other words, the tip part 52 is parallel to the plate surface of the control substrate 40 and is disposed so as to be superimposed on the solder 42 in plan view (in the case of viewing from the Z-axis direction).

An electronic component (not illustrated) is mounted on the front surface 40B of the control substrate 40, while a conductive pattern 41 is formed on the back surface 40A (the surface facing the case; in other words, the surface on the side opposite from the direction of bending of the bent part 50). The conductive pattern 41 is a site where the potential thereof serves as the ground potential of a circuit formed on the control substrate 40. The conductive pattern 41 is electrically connected to a ground pattern 44 formed on the front surface 40B (component mounting surface) via a through-hole 43 formed by passing through the control substrate 40, for example.

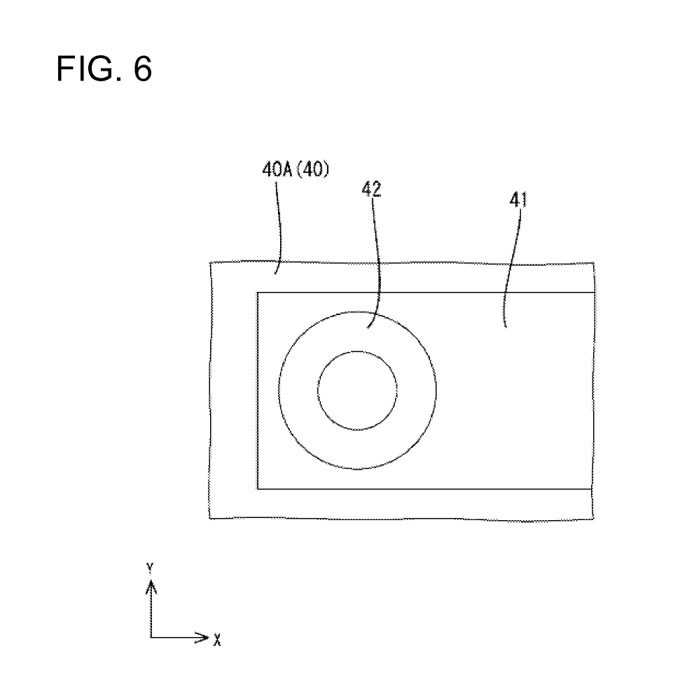

The solder 42 is formed in a location on the conductive pattern 41 that faces the tip part 52 of the bent part 50. As a result of this solder 42 contacting the tip part 52, the two are electrically connected. The configuration is such that this establishes the electrical connection between the conductive pattern 41 and the underside cabinet Cb. The solder 42 has a doughnut shape (endless annular shape) in the plan view of FIG. 6. The height of the solder 42 (the height from the conductive pattern 41) is set at a value at which the tip part 42A of the solder 42 (the tip on the back side) comes into contact with (touches) the front-side surface 52B of the tip part 52 of the bent part 50.

As described above, in the liquid crystal display device 10 of the present embodiment, a configuration is adopted in which the conductive pattern 41 to be applied with the ground potential of the control substrate 40 is electrically connected to the underside cabinet Cb (bent part 50) that has conductive properties. Consequently, the ground potential of the conductive pattern 41 can be stabilized, and the control substrate 40 is not easily subjected to the effect of noise, so the operational reliability thereof is improved.

Next, a description will be given regarding the effect obtained by forming the solder 42 that makes electrical connection between the conductive pattern 41 and the bent part 50 in an endless annular shape in plan view. In general, solder in a molten state is such that the central portion bulges due to surface tension, while the end portion becomes lower than the central portion. Therefore, in cases where the case and the conductive pattern are connected via a solder, the end portion of the solder becomes a site that is harder to make contact with the case than the central portion thereof. If a case is supposed in which the contact with the case is made solely by the central portion of the solder, the contact surface area between the solder and the case becomes small, so lowering reliability of electrical connection becomes a concern.

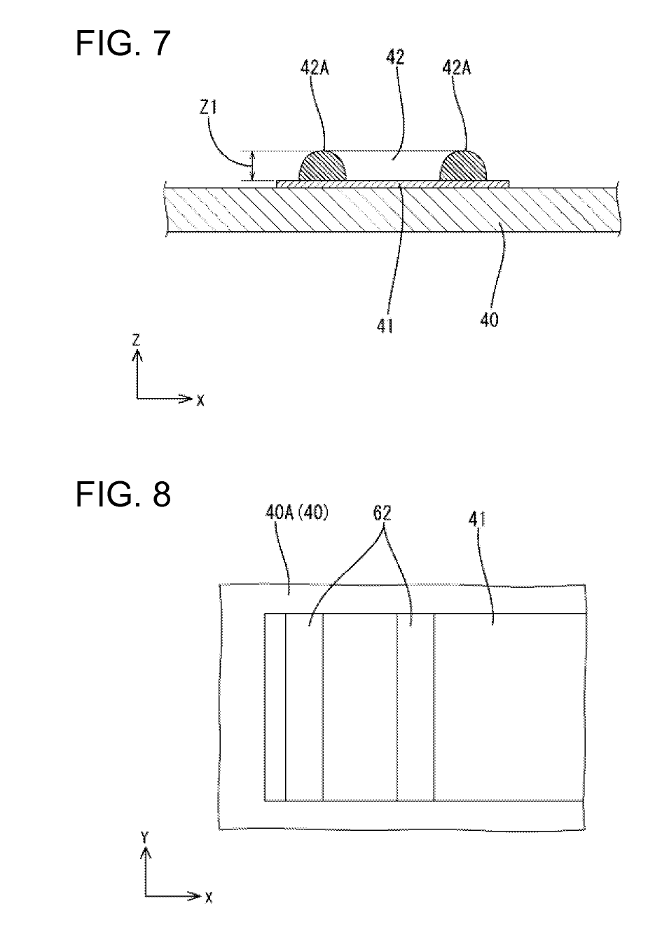

In light of this, the solder 42 is formed in a doughnut shape in the present embodiment. With a doughnut-like endless annular shape, there is no end portion in the circumferential direction of the solder 42, so the height Z1 from the conductive pattern 41 (hence, the height from the control substrate 40) easily becomes uniform over the entire circumference as shown in FIG. 7. Consequently, the tip part 52 of the solder 42 can be caused to contact the tip part 52 of the bent part 50 reliably over the entire circumference thereof, so it is possible to improve the reliability of an electrical connection between the conductive pattern 41 and the underside cabinet Cb. This makes it possible to stabilize the ground potential of the control substrate 40 further and to reduce the effect of noise. Therefore, the operational reliability of the control substrate 40 can be increased further, and the control of the liquid crystal panel 11 can be performed in a more stable manner.

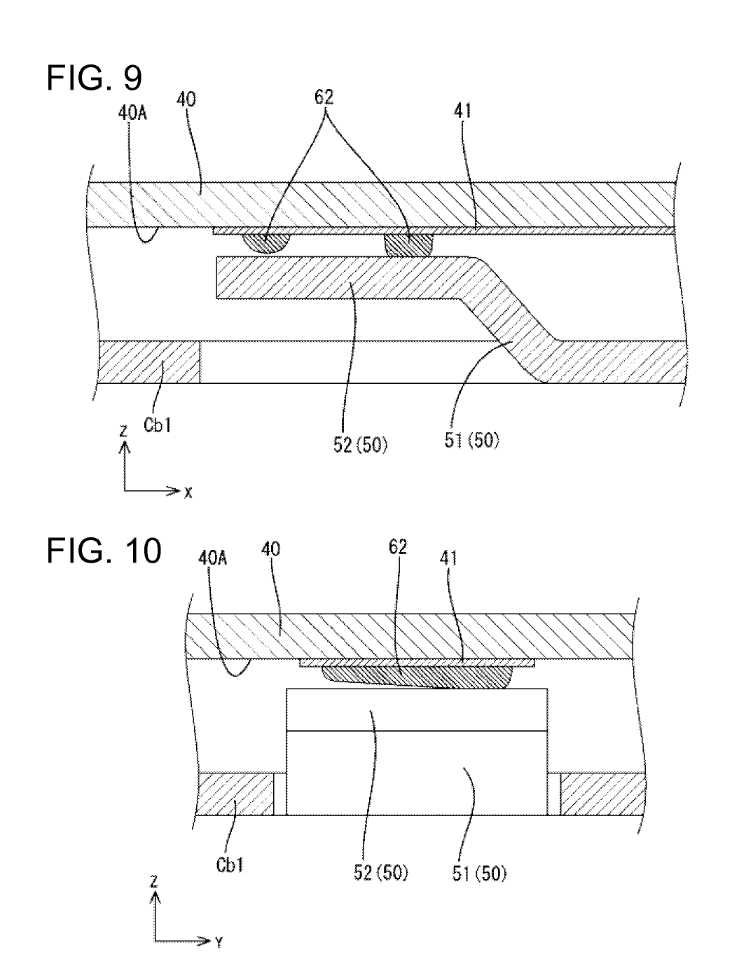

In addition, in cases where a configuration is adopted in which the connection between the conductive pattern 41 and the tip part 52 is established by solders 62 in two parallel rows that extend in one direction (Y-axis direction) as shown in FIG. 8, for example, there are instances in which a difference is created in the height of the respective solders 62 as shown in FIG. 9. In such instances, there is a risk of not touching the tip part 52 as in the solder 62 on the left side of FIG. 9. Furthermore, a case may also occur in which the height of the solders 62 is not uniform in the direction of length (Y-axis direction) as shown in FIG. 10. In this case as well, there is a risk of the area of contact between the solders 62 and the tip part 52 becoming small. In this respect, because the solder 42 is formed in a doughnut shape in the present embodiment, the aforementioned problems do not occur, either.

Note that in the present embodiment, the connection between each of the inverter substrates 30 and the corresponding bent part 50 is also performed via a doughnut-shaped solder 42 as in the case with the control substrate 40. Therefore, the ground potential of each inverter substrate 30 can be made more stable, and the operational reliability can be increased; as a result, the driving control of the cold cathode tubes 17 can be performed in a more stable manner.

Moreover, because the respective conductive patterns of the control substrate 40 and two inverter substrates 30 are connected to the underside cabinet Cb, the ground potentials of the respective conductive patterns can be made equal, so it is possible to enhance the operational reliability of the control substrate 40 and two inverter substrates 30 even further.

In addition, a bent part 50 is formed by stamping and bending a portion of the underside cabinet Cb toward the control substrate 40, and the solder 42 is electrically connected to the bent part 50. When a configuration is adopted in which the control substrate 40 and the underside cabinet Cb are electrically connected in this manner via the bent part 50 which is a portion of the underside cabinet Cb, there is no need for a separate member (e.g., on-board contact) for electrically connecting between the control substrate 40 and the underside cabinet Cb, so the cost can be reduced.

Furthermore, the control substrate 40 is disposed so as to face the bottom plate Cb1 of the underside cabinet Cb, and a portion of the bottom plate Cb1 is formed as a bent part 50. If a portion of the bottom plate Cb1 facing the control substrate 40 is formed as the bent part 50, the amount of bending of the bottom plate Cb1 that is required in the formation of the bent part 50 can be relatively small, so the formation of the bent part 50 becomes easy.

Moreover, the bent part 50 has the inclined part 51 that is inclined toward the control substrate 40 and the tip part 52 that extends from the tip of the inclined part 51 along the plate surface of the control substrate 40 and that contacts the corresponding solder 42. With the configuration in which the tip part 52 that extends along the plate surface of the control substrate 40 is caused to contact the solder 42, the inclination of the solder 42 toward the tip part 52 can be suppressed, so soldering of the underside cabinet Cb with the control substrate 40 can be performed more reliably.

In addition, the conductive pattern 41 is formed on the surface of the control substrate 40 that faces the underside cabinet Cb (to be exact, the bottom plate Cb1 thereof). When this configuration is adopted in which the conductive pattern 41 and the underside cabinet Cb are caused to face each other, it becomes easy for the conductive pattern 41 and the underside cabinet Cb to make contact, so the soldering of the two (connection via the solder 42) can be performed easily.

Furthermore, the underside cabinet Cb constitutes an external box that defines the external appearance of the liquid crystal display device 10. By doing so, the size of the underside cabinet Cb (i.e., the size of the conductor) can easily be set to be large, so the ground potential of the control substrate 40 can be made more stable.

### Embodiment 2

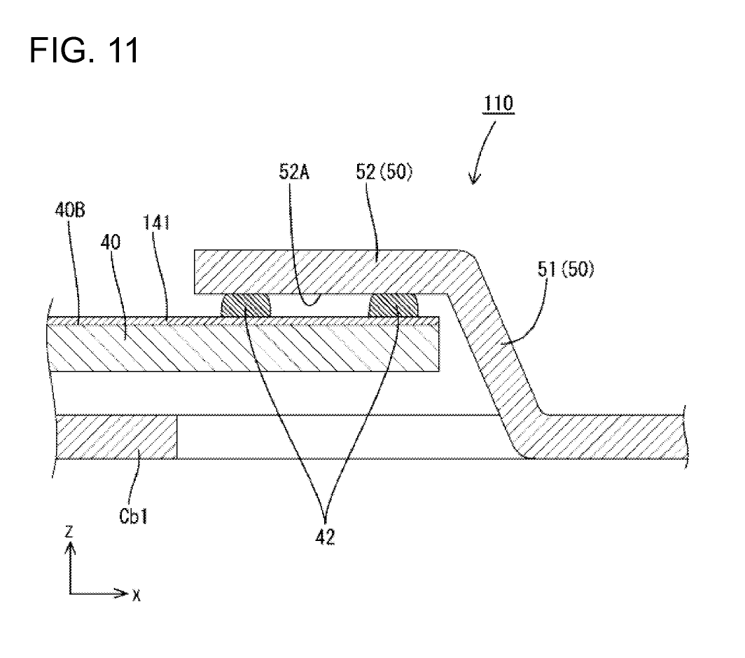

Embodiment 2 of the present invention will be described based on FIG. 11. The parts that are the same as in the aforementioned embodiment are assigned the same reference characters, and a redundant description will be omitted. In the liquid crystal display device 110 of the present embodiment, a conductive pattern 141 to be applied with a ground potential is formed on the front-side surface 40B of the control substrate 40. A solder 42 formed on the conductive pattern 141 makes contact with the back-side surface 52A (in other words, the surface on the side opposite from the direction of bending of the bent part 50) of the tip surface 52 of the bent part 50. In this configuration as well, the ground potential of the control substrate 40 can be stabilized in a similar manner as in Embodiment 1.

Moreover, in the present embodiment, the configuration is such that the conductive pattern 141 formed on the surface 40B of the control substrate 40 (component mounting surface) and the bent part 50 are connected. Therefore, it is not necessary to form a through-hole 43 such as the one in Embodiment 1 to electrically connect the wiring patterns on the front and back surfaces of the control substrate 40 to each other.

### Embodiment 3

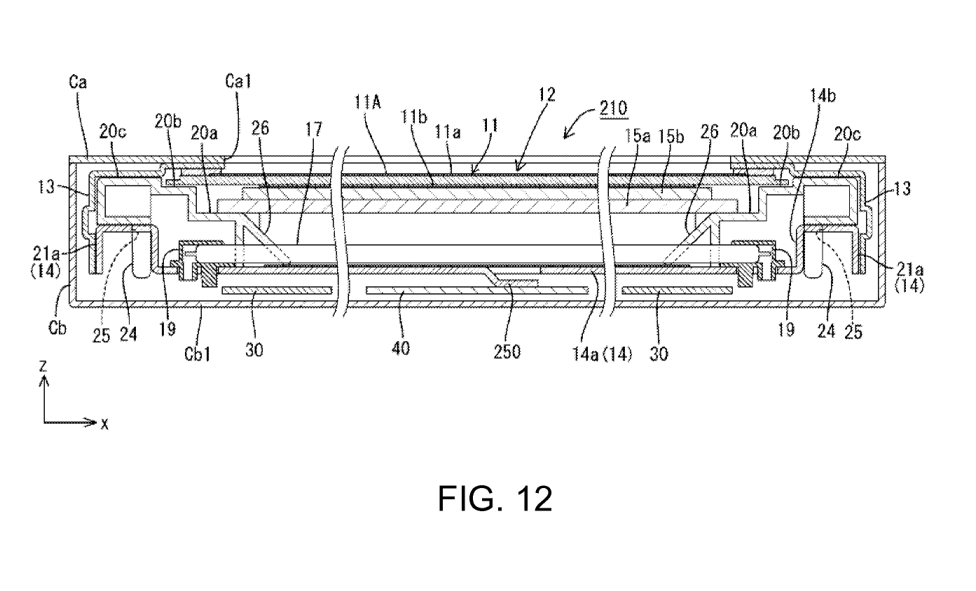

Embodiment 3 of the present invention will be described based on FIG. 12. The parts that are the same as in the aforementioned respective embodiments are assigned the same reference characters, and a redundant description will be omitted. In the liquid crystal display devices 10 and 110 of the aforementioned respective embodiments, a configuration was adopted in which a bent part 50 is formed by bending a portion of the underside cabinet Cb, and this bent part 50 is electrically connected to the control substrate 40 (or one of the inverter substrates 30). In the liquid crystal display device 210 of the present embodiment, a bent part 250 is formed by stamping a portion (bottom plate 14a) of the chassis 14 and bending it toward the back side (toward the control substrate 40, the lower side in FIG. 12).

The bent part 250 is electrically connected to a conductive pattern 141 (not shown in FIG. 12) that serves as the ground potential of the control substrate 40 via a doughnut-shaped solder 42 in the same manner as in the aforementioned respective embodiments. The chassis 14 is made of aluminum, for example, and has conductive properties. Therefore, by electrically connecting the chassis 14 and the conductive pattern 141, the ground potential of the control substrate 40 can be stabilized, so the operational reliability of the control substrate 40 can be increased further. Note that it is also possible to adopt a configuration in which the bent part 250 is connected to an inverter substrate 30. In addition, in the present embodiment, the configuration is such that the chassis 14 and the control substrate 40 are electrically connected, so it is not necessary to form the two cabinets Ca and Cb from a material having conductive properties. For instance, the two cabinets Ca and Cb may be made of synthetic resin having relatively low conductive properties, which can reduce the material cost.

### Embodiment 4

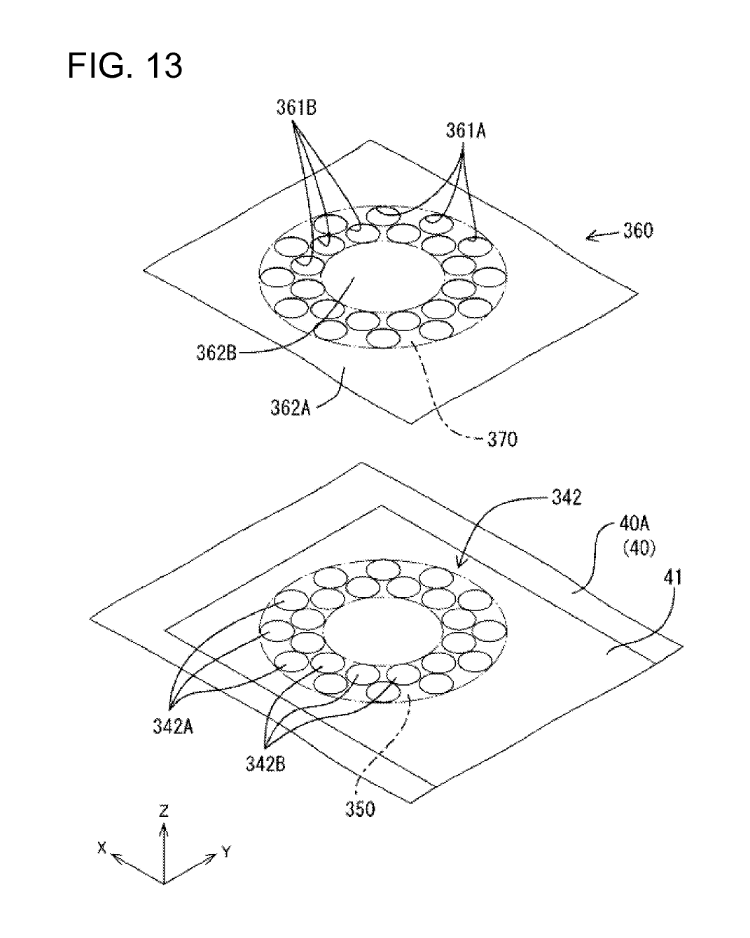

Embodiment 4 of the present invention will be described based on FIG. 13. The parts that are the same as in the aforementioned respective embodiments are assigned the same reference characters, and a redundant description will be omitted. In the present embodiment, the shape of a solder 342 for making an electrical connection between the conductive pattern 41 (control substrate 40) and the bent part 50 (not shown in FIG. 13) is different from that of the aforementioned embodiments.

FIG. 13 is a perspective view showing a state in which the solder 342 is formed on the conductive pattern 41 using a metal mask 360. The solder 342 in the present embodiment forms an annular shape as a whole by being configured from a plurality of solder pieces arranged in an annular shape as shown in FIG. 13. To elaborate further, the individual solder pieces are in a double annular arrangement. In the following description, each of the individual solder pieces disposed on the outside in an annular shape is called a solder outer circumferential part 342A, and each of the individual solder pieces disposed on the inside in an annular shape is called a solder inner circumferential part 342B. Furthermore, each of the solder outer circumferential parts 342A and solder inner circumferential parts 342B is in a hemispherical shape (circular shape in plan view), for example.

One solder inner circumferential part 342B is disposed approximately in the central position between two adjacent solder outer circumferential parts 342A in the circumferential direction of the solder 342 (in other words, one solder outer circumferential part 342A is disposed approximately in the central position between two adjacent solder inner circumferential parts 342B in the circumferential direction). Moreover, the formation is such that one solder inner circumferential part 342B is in close proximately to (or in contact with) both of two adjacent solder outer circumferential parts 342A.

The metal mask 360 for forming the solder 342 is a thin metal plate (e.g., brass and stainless steel). A plurality of outer circumferential holes 361A for forming the solder outer circumferential parts 342A and a plurality of inner circumferential holes 361B for forming the solder inner circumferential parts 342B are formed in the metal mask 360. The individual outer circumferential holes 361A are formed in a shape (circular shape in plan view) and in an arrangement (annular arrangement) corresponding to the respective solder outer circumferential parts 342A. Likewise, the individual inner circumferential holes 361B are formed in a shape (circular shape in plan view) and in an arrangement (annular arrangement) corresponding to the respective solder inner circumferential parts 342B.

Two adjacent outer circumferential holes 361A in the circumferential direction are disposed with a slight gap left open, and two adjacent inner circumferential holes 361B in the circumferential direction are also disposed with a slight gap left open. In addition, each one of the inner circumferential holes 361B is disposed with a slight gap left open from both of two adjacent outer circumferential holes 361A in the circumferential direction, though in close proximity thereto. That is, a configuration is adopted in which the inner portion 362B surrounded by the individual inner circumferential holes 361B and the portion 362A outside of the outer circumferential holes 361A are linked in the metal mask 360.

Note that it is not necessary to dispose all of two adjacent outer circumferential holes 361A (or inner circumferential holes 361B) with a gap left open. In essence, it is sufficient as long as the individual outer circumferential holes 361A and the individual inner circumferential holes 361B are formed in a manner linking the inner portion 362B and the outer portion 362A in the metal mask 360. For example, two adjacent outer circumferential holes 361A (or inner circumferential holes 361B) may be formed in a linked (communicated) manner. Furthermore, it may include an outer circumferential hole 361A that is communicated with an inner circumferential hole 361B in close proximity thereto.

Next, the procedure for forming the solder 342 using this metal mask 360 will be described. First, the metal mask 360 is set so as to cover the surface of the conductive pattern 41, and a solder material (solder cream) is applied (printed) from above the metal mask 360. Consequently, the solder material passes through the individual outer circumferential holes 361A and the individual inner circumferential holes 361B, so solder outer circumferential parts 342A are formed in portions corresponding to the outer circumferential holes 361A, while solder inner circumferential parts 342B are formed in portions corresponding to the inner circumferential holes 361B.

After the solder 342 is printed, the solder 342 is heated and melted by a heating means (e.g., reflow device) that is not illustrated in a state of being in contact with the bent part 50. This establishes the electrical connection between the conductive pattern 41 and the bent part 50.

Moreover, during the application of or during the reflow of the solder outer circumferential parts 342A and solder inner circumferential parts 342B, each of the solder outer circumferential parts 342A and each of the solder inner circumferential parts 342B are melted, so adjacent ones of the individual solder outer circumferential parts 342A and individual solder inner circumferential parts 342B are mixed together. Consequently, adjacent ones of the individual solder outer circumferential parts 342A and individual solder inner circumferential parts 342B are linked, so the solder 342 forms an endless annular shape as a whole in plan view. Note that in FIG. 13, in order to make the individual solder outer circumferential parts 342A and the individual solder inner circumferential parts 342B easier to see, each of these is illustrated in a non-linked state.

Next, a description will be given regarding the effects obtained by configuring the solder 342 from a plurality of solder outer circumferential parts 342A and solder inner circumferential parts 342B. In the present embodiment, as a result of the solder 342 being configured from small solder pieces such as the solder outer circumferential parts 342A and solder inner circumferential parts 342B, the individual solder outer circumferential parts 342A and the individual solder inner circumferential parts 342B are such that the respective heights thereof tend to become uniform easily due to surface tension. Consequently, the solder 342 can be formed at a uniform height over the entire circumference thereof, so the reliability of an electrical connection between the conductive pattern 41 and the bent part 50 can be improved.

In addition, by configuring from the plurality of solder outer circumferential parts 342A and solder inner circumferential parts 342B, the amount of solder used can be reduced compared to an annular solder 350 with the same width (shown with a one-dot chain line in FIG. 13).

Furthermore, when the shape of the solder 342 is to be modified, the modification can be made easily by appropriating changing the shape and number of the individual outer circumferential holes 361A and individual inner circumferential holes 361B of the metal mask 360.

Moreover, by configuring the solder 342 from the solder outer circumferential parts 342A and solder inner circumferential parts 342B, an endless annular solder 342 can be formed using the metal mask 360. To describe this in detail, if an endless annular hole 370 (one-dot chain line in FIG. 13) that is continuous over the entire circumference were formed in the metal mask 360, the inner portion 362B surrounded by the hole 370 would be separated from the metal mask 360. That is, what is formed in the metal mask 360 is inevitably not an annular hole, but a circular hole.

In this regard, when the solder 342 is configured from the solder outer circumferential parts 342A and the solder inner circumferential parts 342B as in the present embodiment, the outer circumferential holes 361A and the inner circumferential holes 361B may be formed such that a state is created in which the inner portion 362B surrounded by the individual inner circumferential holes 361B and the portion 362A outside of the outer circumferential holes 361A are linked in the metal mask 360. Because of this, there is no separation of the inner portion 362B from the metal mask 360, so the function of the mask can be assumed. Thus, the endless annular solder 342 can be formed by using the metal mask 360.

Note that a case was exemplified in which the solder 342 is configured from the solder outer circumferential parts 342A and the solder inner circumferential parts 342B, but the solder is not limited to this. The solder 342 may be configured from a plurality of solder pieces arranged in an annular shape, and the shape, disposition, and the like of the solder outer circumferential parts 342A and solder inner circumferential parts 342B can be modified as appropriate. In addition, the solder pieces configuring the solder 342 are in a double annular arrangement, but the arrangement is not limited to this, and a single or triple or more annular arrangement, for example, may also be used.

### Other Embodiments

The present invention is not limited to the embodiments described based on the aforementioned description and figures, and the following embodiments, for instance, are also included in the technological scope of the present invention.
(1) In each of the aforementioned embodiments, a configuration in which the solder 42 has a doughnut shape in plan view was described as an example, but the solder is not limited to this. Solder 42 may be in any annular shape having ends; for example, the solder may be in a square frame shape in plan view or in a D shape in plan view.
(2) In each of the aforementioned embodiments, solder 42 may also be formed in a plurality of locations on the conductive pattern 41 or 141.
(3) In each of the aforementioned embodiments, the inverter substrates 30 and the control substrate 40 were shown as examples of the control substrate electrically connected to the case, but only one of the inverter substrates 30 and control substrate 40 may be electrically connected to the case. Furthermore, the control substrate electrically connected to the case is not limited to the aforementioned two types of substrates 30 and 40, and the present invention can be applied to any type of control substrate as long as it is a control substrate that performs display-related control of the liquid crystal display device 10.
(4) The connection between the front-side cabinet Ca and the control substrate 40 may be made without interposing a bent part 50, and it is possible to adopt a configuration in which the front-side cabinet Ca and the control substrate 40 are electrically connected via a separate member. Moreover, a configuration is also possible in which the tip part 52 and the bottom plate Cb1 are linked by a linking part that is orthogonal (not inclined) to the control substrate 40 in place of the inclined part 51 constituting a bent part 50.
(5) The materials for the two cabinets Ca and Cb and chassis 14 are not limited to the ones exemplified in the aforementioned respective embodiments. The two cabinets Ca, Cb or the chassis 14 needs to be made of conductive material when it is electrically connected to the control substrate (control substrate 40 or inverter substrates 30).
(6) In each of the aforementioned embodiments, a backlight device of a type having the cold cathode tubes 17 constituting the light source disposed directly below the liquid crystal panel 11 (so-called direct type) exemplifies the backlight device 12, but the present invention may also be applied to a backlight device of a type having the light source disposed to a side (so-called side-light type).
(7) In each of the aforementioned embodiments, a display device was shown in which the cold cathode tubes 17 are present so as to extend along the direction of the long side (X-axis direction) of the chassis 14, but the cold cathode tubes 17 may be present so as to extend along the direction of the short side (Y-axis direction) of the chassis 14.
(8) In each of the aforementioned embodiments, the case of using the cold cathode tubes 17 as the light source was shown, but other types of light source may also be used; for example, hot cathode tubes or LEDs may also be used.
(9) In each of the aforementioned embodiments, a liquid crystal display device using a liquid crystal panel is described as an example of the display panel, but the present invention can be applied to a display device using other types of display panel.
(10) In each of the aforementioned embodiments, TFTs were used as the switching elements of the liquid crystal display device, but the present invention can be applied to a liquid crystal display device using the switching elements other than TFTs (e.g., thin-film diodes (TFDs)) and can also be applied to a black and white display liquid crystal display device other than a color display liquid crystal display device.

### DESCRIPTION OF REFERENCE CHARACTERS

10 liquid crystal display device (display device)
11 liquid crystal panel (display panel)
14 chassis (case)
14a, Cb1 bottom plate (bottom wall of case)
17 cold cathode tube (light source)
30 inverter substrate (light-source control substrate, control substrate)
40 control substrate (display control substrate, control substrate)
40A back surface of control substrate (surface of control substrate facing case)
41, 141 conductive pattern
42, 342 solder
50 bent part (a portion of case)
51 inclined part
52 tip part
Ca front-side cabinet (case)
Cb underside cabinet (case)

1: A display device, comprising:
a display panel;
a case that supports said display panel, the case being electrically conductive;
a control substrate that performs display-related control;
a conductive pattern to be applied with a ground potential, formed on said control substrate; and
a solder that electrically connects said conductive pattern to said case, the solder being formed on this conductive pattern,
wherein said solder has an endless annular shape in plan view.

2: The display device according to claim 1, wherein said control substrate is a display control substrate that performs display control of said display panel.

3: The display device according to claim 1, further comprising:
a light source that supplies light to said display panel,
wherein said control substrate is a light-source control substrate that performs driving control of said light source.

4: The display device according to claim 1, wherein a bent part is formed by stamping and bending a portion of said case toward said control substrate, and
wherein said solder is electrically connected to said bent part.

5: The display device according to claim 4, wherein said control substrate is disposed so as to face a bottom wall of said case, and said bent part is a portion of said bottom wall.

6: The display device according to claim 4, wherein said bent part has an inclined part that is inclined toward said control substrate, and a tip part that extends from a tip of said inclined part along a planar surface of said control substrate, the tip part being in contact with said solder.

7: The display device according to claim 1, wherein said conductive pattern is formed on a surface of said control substrate facing said case.

8: The display device according to claim 1, wherein said case is an external box defining external appearance of the display device.

9: The display device according to claim 1, wherein said display panel is a liquid crystal panel using a liquid crystal.
